(19) United States
(12) Patent Application Publication
(10) Pub. No.: US 2025/0069909 A1
(43) Pub. Date: Feb. 27, 2025

(54) SUBSTRATE PROCESSING APPARATUS, SUBSTRATE PROCESSING METHOD, AND SEMICONDUCTOR DEVICE MANUFACTURING METHOD

(71) Applicant: Kioxia Corporation, Tokyo (JP)

(72) Inventors: Ryutaro OTAHARA, Yokkaichi Mie (JP); Yoshihito KOBAYASHI, Kawasaki Kanagawa (JP)

(73) Assignee: Kioxia Corporation, Tokyo (JP)

(21) Appl. No.: 18/807,038

(22) Filed: Aug. 16, 2024

(30) Foreign Application Priority Data
Aug. 25, 2023 (JP) 2023-136934

(51) Int. Cl. H01L 21/67

(52) U.S. Cl. CPC H01L 21/6708

(57) ABSTRACT

A substrate processing apparatus includes a holder configured to hold a substrate; a supply nozzle configured to provide a treatment liquid to the substrate; a rotation driver configured to rotate the substrate; a receiving portion configured to receive the treatment liquid scattered from the substrate; an electrode provided on a surface of the receiving portion and configured to receive the treatment liquid; an insulator covering an electrode surface of the electrode; and a voltage controller configured to control a voltage to be applied to the electrode.

### CROSS-REFERENCE TO RELATED APPLICATION

This application is based upon and claims the benefit of priority from Japanese Patent Application No. 2023-136934, filed Aug. 25, 2023, the entire contents of which are incorporated herein by reference.

### FIELD

Embodiments described herein relate generally to a substrate processing apparatus, a substrate processing method, and a semiconductor device manufacturing method.

### BACKGROUND

Substrate processing apparatuses that process a substrate by supplying a treatment liquid to a substrate surrounded by a cup and then rotating the substrate to diffuse the treatment liquid onto the surface of the substrate have been commonly used.

### DESCRIPTION OF THE DRAWINGS

FIG. 1 is a cross-sectional view showing a cross-sectional structure of a semiconductor device of the present embodiment;

FIG. 2 is a cross-sectional view showing a cross-sectional structure around a memory layer of the semiconductor device of the present embodiment;

FIG. 3 is a schematic diagram showing a schematic configuration of a substrate processing apparatus according to the present embodiment;

FIG. 4 is a plan view of the inside of a receiving portion viewed from below;

FIG. 5 is a plan view of the inside of the receiving portion viewed from below;

FIG. 6 is an enlarged view of main portions of a substrate processing portion;

FIG. 7 is a diagram showing an operation of the substrate processing portion;

FIG. 8 is a diagram showing an operation of the substrate processing portion;

FIG. 9 is a timing chart of a sequence diagram showing a flow of processing of the substrate processing apparatus;

FIG. 10 is a flowchart showing a flow of a substrate processing method executed by the substrate processing apparatus;

FIG. 11 is a schematic diagram showing a schematic configuration of a substrate processing portion according to another embodiment;

FIG. 12 is a schematic diagram showing an example of an insulating portion of a substrate processing portion according to another embodiment;

FIG. 13 is a schematic diagram showing an example of an insulating portion of a substrate processing portion according to another embodiment; and

FIG. 14 is a schematic diagram showing a schematic configuration of a substrate processing apparatus according to another embodiment.

### DETAILED DESCRIPTION

Embodiments provide a substrate processing apparatus, a substrate processing method, and a semiconductor device manufacturing method that are capable of smoothly discharging a treatment liquid scattered from a substrate.

In general, according to one embodiment, a substrate processing apparatus includes a holder configured to hold a substrate; a supply nozzle configured to provide a treatment liquid to the substrate; a rotation driver configured to rotate the substrate; a receiving portion configured to receive the treatment liquid scattered from the substrate; an electrode provided on a surface of the receiving portion and configured to receive the treatment liquid; an insulator covering an electrode surface of the electrode; and a voltage controller configured to control a voltage to be applied to the electrode.

Hereinafter, one embodiment of a substrate processing apparatus, a substrate processing method, and a semiconductor device manufacturing method will be described with reference to the drawings. A semiconductor device of the present embodiment will be described using a nonvolatile memory device configured as a NAND flash memory as an example, but the structure of the semiconductor device is not particularly limited.

### (Configuration of Semiconductor Device)

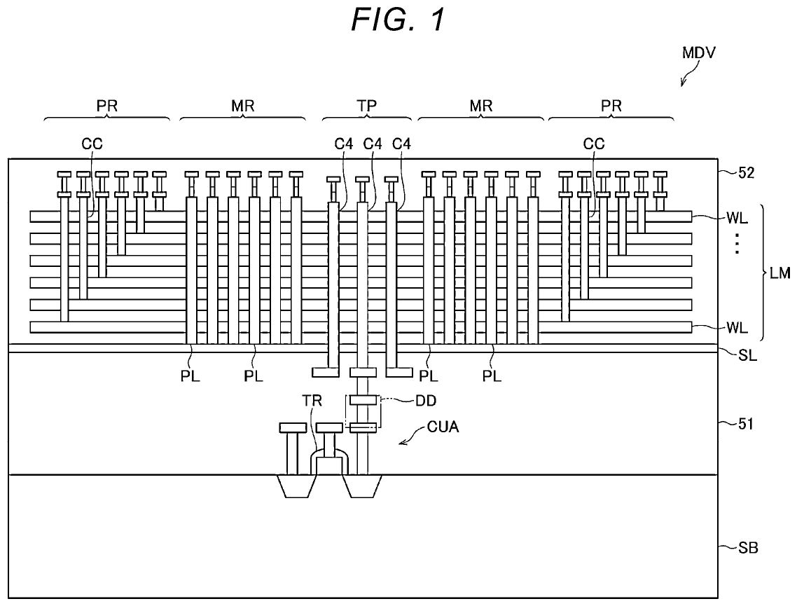

FIG. 1 is a cross-sectional view showing a schematic configuration of a semiconductor device MDV of the present embodiment. In FIG. 1, hatching indicating a cross-sectional portion is omitted to improve the visibility of the drawing.

As shown in FIG. 1, the semiconductor device MDV includes a peripheral circuit CUA, a source line SL, and a stacked body LM. The peripheral circuit CUA, the source line SL, and the stacked body LM are formed on a substrate SB in this order. The substrate SB is a silicon substrate or the like.

The peripheral circuit CUA includes a transistor TR and the like, and contributes to an electrical operation of a memory cell, that will be described later. The transistor TR is formed on the substrate SB. The peripheral circuit CUA is covered with an insulating film 51. The insulating film 51 is a silicon oxide film or the like. The source line SL is formed on the insulating film 51. The source line SL is a conductive polysilicon layer or the like.

The stacked body LM is formed on the source line SL. The stacked body LM includes a plurality of stacked word lines WL. The word line WL is a tungsten layer, a molybdenum layer, or the like. An insulating layer is interposed between the plurality of word lines WL. The insulating layer is a silicon oxide layer or the like.

The stacked body LM includes a memory region MR, a contact region PR, and a through contact region TP. A plurality of pillars PL and a plurality of contacts CC and C4 are provided in each of the regions MR, PR, and TP. The entire stacked body LM is covered with an insulating film 52. The insulating film 52 is a silicon oxide film or the like.

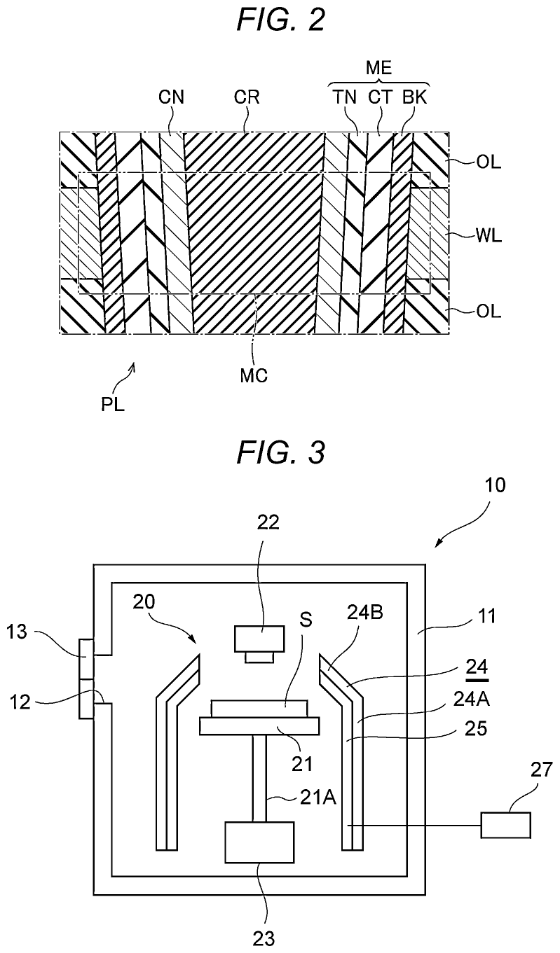

Each of the plurality of pillars PL passes through the stacked body LM and reaches the source line SL. FIG. 2 shows a detailed configuration of the pillar PL.

As shown in FIG. 2, the pillar PL includes a memory layer ME and a channel layer CN. The memory layer ME and the channel layer CN are disposed in this order from the outer periphery of the pillar PL. A core layer CR is filled in the channel layer CN. The memory layer ME has a multilayer structure in which a block insulating layer BK, a charge storage layer CT, and a tunnel insulating layer TN are stacked. The block insulating layer BK, the charge storage layer CT, and the tunnel insulating layer TN are disposed in this order from the outer periphery of the pillar PL. The memory layer ME is not disposed at a lower end of the pillar PL, and the channel layer CN provided inside the memory layer ME is connected to the source line SL.

The channel layer CN is, for example, a semiconductor layer such as a polysilicon layer or an amorphous silicon layer. The core layer CR, the tunnel insulating layer TN, and the block insulating layer BK are, for example, silicon oxide layers. The charge storage layer CT is, for example, a silicon nitride layer.

A symbol OL shown in FIG. 2 represents an insulating layer formed between the plurality of word lines WL.

With such a configuration, a plurality of memory cells MC arranged in a height direction are formed at an intersection of the pillar PL and the word line WL. By applying a predetermined voltage from the word line WL to the memory cell MC, charges can be accumulated in the charge storage layer CT of the memory cell MC, or charges can be extracted from the charge storage layer CT. Data is written into or read from the memory cell MC by accumulating charges in the charge storage layer CT or extracting charges from the charge storage layer CT. The data read from the memory cell MC is transmitted to, for example, a sense amplifier of the semiconductor device MDV via a plug, an upper layer wiring, and the like provided above the pillar PL.

Each of the plurality of contacts CC shown in FIG. 1 extends to a depth where the contact is connected to any one of the plurality of word lines WL provided in the stacked body LM. Each of the plurality of contacts CC is connected to the plurality of contacts C4 via an upper layer wiring and a plug.

The plurality of contacts C4 extend to the insulating film 51 provided below the stacked body LM via the stacked body LM and the source line SL. Lower end portions of the plurality of contacts C4 are connected to the transistor TR of the peripheral circuit CUA in the insulating film 51 via a lower layer wiring, vias, contacts, and the like.

With such a configuration, the memory cells MC can be operated electrically by applying a predetermined voltage to each of the memory cells MC from the peripheral circuit CUA via the contacts C4 and CC.

### (Configuration of Substrate Processing Apparatus)

Next, a configuration of a substrate processing apparatus 10 used in a manufacturing process of the above-mentioned semiconductor device MDV will be described. The substrate processing apparatus 10 of the embodiment is, for example, a wet etching apparatus that performs wet etching of a wafer in a manufacturing process of the semiconductor device MDV, or a clean track that performs coating and development.

FIG. 3 is a diagram showing an example of a schematic configuration of the substrate processing apparatus 10. A substrate S that is, for example, a semiconductor substrate (wafer) on which the semiconductor device MDV in the middle of manufacture is formed, is carried into the substrate processing apparatus 10. For example, the peripheral circuit CUA (see FIG. 1) such as a transistor may be formed on the substrate S.

The substrate processing apparatus 10 includes a box-shaped housing 11, and the housing 11 is provided with a carry-in port 12 into which the substrate S can be carried. The carry-in port 12 is configured to be openable and closable by a movable cover member 13. A substrate processing portion 20 processing the substrate S using a treatment liquid is provided inside the housing 11.

The substrate processing portion 20 includes, for example, a holding portion 21 (holding plate, holding table or holder), a supply portion 22 (supply nozzle), a rotation driving portion 23 (rotation driver), a receiving portion 24 (cup), an electrode 25, an insulator 26 (insulating film), and a voltage control portion 27 (voltage control circuit or voltage controller).

The holding portion 21 holds the substrate S carried into the housing 11 through the carry-in port 12. The holding portion 21 is connected to the rotation driving portion 23 via a shaft portion 21A extending in a vertical direction. The holding portion 21 is configured to be rotatable about the shaft portion 21A by driving the rotation driving portion 23. The rotation driving portion 23 includes, for example, a motor control circuit that controls rotation drive units such as a motor.

The supply portion 22 is disposed to face the substrate S held by the holding portion 21 in the vertical direction, and is configured to be able to discharge a treatment liquid used for processing the substrate S. As the treatment liquid, for example, ultrapure water, hydrochloric acid, hydrofluoric acid, and a developing solution (TMAH, TM-Y, IPA, or the like) are discharged.

The receiving portion 24 has a substantially cylindrical shape and includes a main body portion 24A and an extending portion 24B that is bent and extends radially inward from an upper end portion of the main body portion 24A. The extending portion 24B may be disposed above the upper surface of the substrate S held by the holding portion 21, and includes a surface portion that receives a treatment liquid scattered from the substrate S rotated by the rotation driving portion 23. The electrode 25 is provided on the inner circumferential surfaces of the main body portion 24A and the extending portion 24B. The receiving portion 24 is made of a material such as stainless steel (SUS).

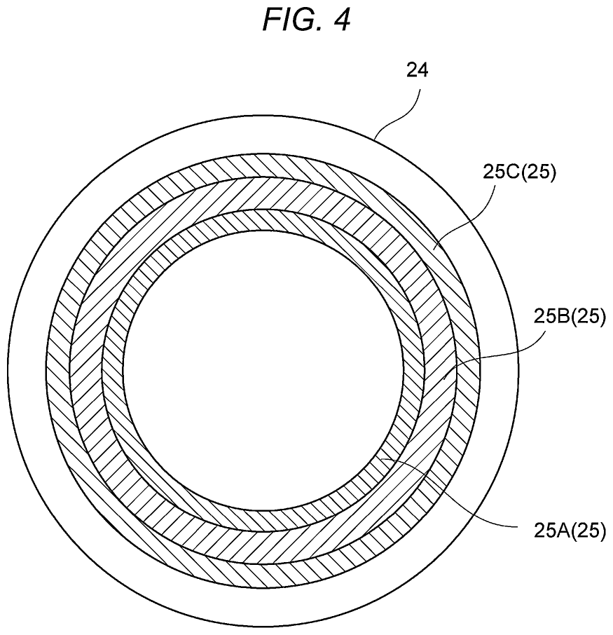

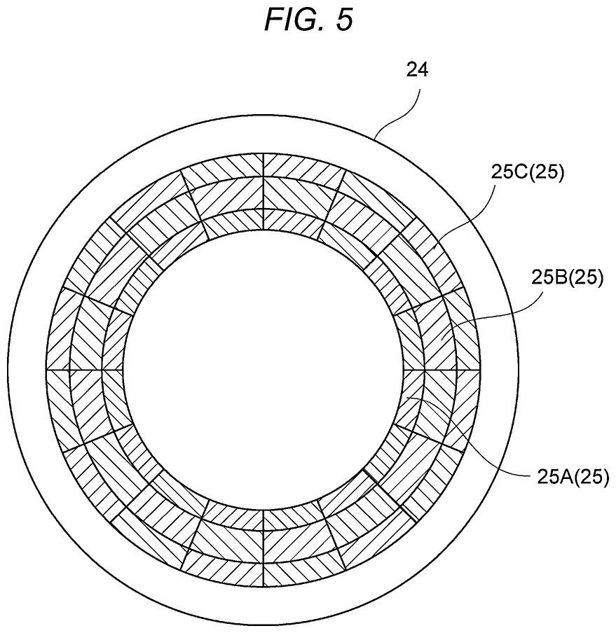

FIGS. 4 and 5 are plan views of the inside of the receiving portion 24 viewed from below.

In the example shown in FIG. 4, the electrode 25 includes, for example, a first electrode 25A, a second electrode 25B, and a third electrode 25C. The first electrode 25A has an annular shape and is provided along an opening at an upper end of the extending portion 24B of the receiving portion 24. The second electrode 25B has an annular shape with an outer diameter larger than that of the first electrode 25A, and is provided adjacent to the first electrode 25A on the lower side of the first electrode 25A in the direction of gravity. The third electrode 25C has an annular shape with an outer diameter larger than that of the second electrode 25B, and is provided adjacent to the second electrode 25B. Each of the first electrode 25A, the second electrode 25B, and the third electrode 25C is configured such that a voltage can be individually applied thereto by the voltage control portion 27. In the example, a phase of the voltage applied to each of the electrodes 25 is controlled by the voltage control portion 27 so that a voltage is applied to each of the first electrode 25A, the second electrode 25B, and the third electrode 25C in this order.

In the example shown in FIG. 5, similarly to the example shown in FIG. 4, the electrode 25 includes, for example, the first electrode 25A, the second electrode 25B, and the third electrode 25C. Each of the first electrode 25A, the second electrode 25B, and the third electrode 25C includes a plurality of electrode units (eight in the example shown in the drawing) that are equally separated in the circumferential direction centering on the center of an opening thereof. A voltage can be individually applied to each of the plurality of electrode units by the voltage control portion 27. In the example, the phase of the voltage applied to each of the electrode units is controlled by the voltage control portion 27 so that different voltages are applied to electrode units adjacent to each other in the circumferential direction. In FIGS. 4 and 5, the respective electrodes (first to third electrodes) 25 are shown to be in contact with each other, but the electrodes 25 may be provided at intervals.

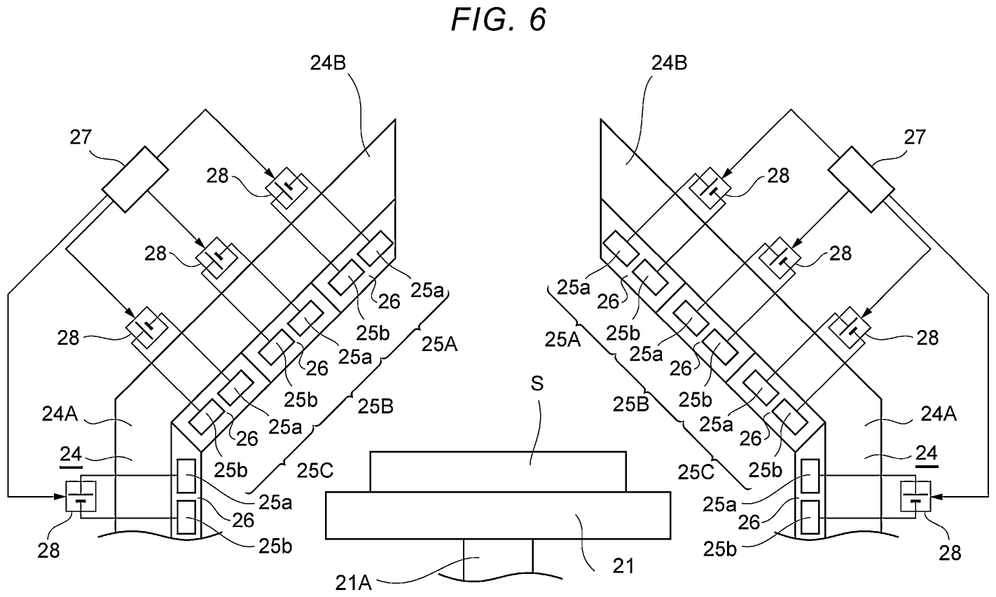

As shown in FIG. 6, each of the first electrode 25A, the second electrode 25B, and the third electrode 25C includes a first terminal portion 25a connected to a positive terminal of a power supply 28, and a second terminal portion 25b connected to a negative terminal of the power supply 28. For each of the first electrode 25A, the second electrode 25B, and the third electrode 25C, voltages supplied from the corresponding power supply 28 are individually controlled by the voltage control portion 27.

The insulator 26 is made of an insulating material, and is configured to cover the entire electrode 25 including an electrode surface and a back surface opposite to the electrode surface of each of the first electrode 25A, the second electrode 25B, and the third electrode 25C.

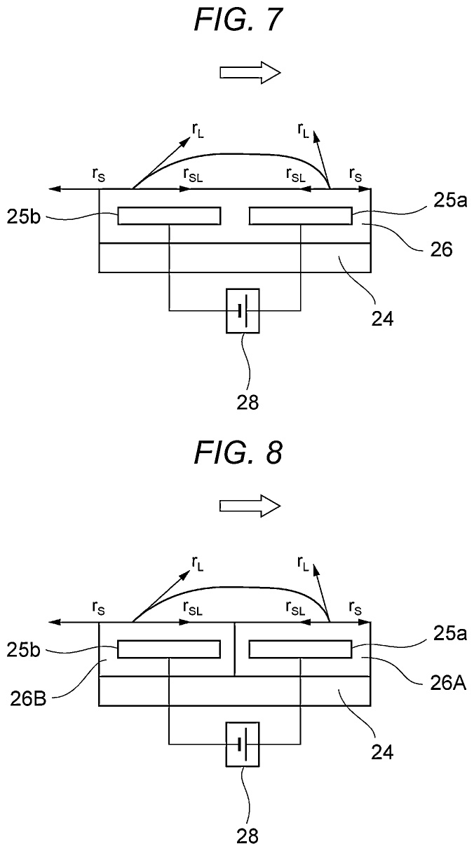

FIG. 7 is a diagram showing an operation of the substrate processing portion 20 according to the present embodiment, particularly when moving a treatment liquid scattered from the substrate S to the receiving portion 24 due to the application of a voltage.

As shown in FIG. 7, when the treatment liquid adheres to the surface of the insulator 26 of the receiving portion 24, a surface tension γ_{S} of the insulator 26, a surface tension γ_{L} of the treatment liquid, and an interfacial tension γ_{SL} between the insulator 26 and the treatment liquid act on the surface of the adhered treatment liquid. The surface tension γ_{S} of the insulator 26 is equivalent to a force with which the insulator 26 spreads the treatment liquid. The surface tension γ_{L} of the treatment liquid is equivalent to a force with which the treatment liquid narrows a surface area. The interfacial tension γ_{SL} between the insulator 26 and the treatment liquid is equivalent to a force with which the treatment liquid narrows a surface area. The figures are expressed by the following Formula (1).

$${γ}_{SL} + {γ}_{L} cos Θ = {γ}_{S} \qquad [ Math . 1 ]$$

In Formula (1), θ represents an angle between the surface tension γ_{L} of the treatment liquid and the surface of the insulator 26.

Here, in the example shown in FIG. 7, out of the first terminal portion 25a and the second terminal portion 25b of the electrode 25, no voltage is applied to the first terminal portion 25a, while a voltage is applied to the second terminal portion 25b. The magnitude of the influence on the treatment liquid due to the application of the voltage to the electrode 25 is expressed by the following Formula (2).

$${γ}_{SL} ( V ) = {γ}_{SLO} - \frac{C}{2} {V}^{2} \qquad [ Math . 2 ]$$

In Formula (2), γ_{SL0} represents an interfacial tension between the insulator 26 and the treatment liquid when no voltage is applied, and γ_{SL}(V) represents an interfacial tension between the insulator 26 and the treatment liquid when a voltage is applied.

Then, the following Formula (3) is calculated by combining the above-mentioned Formulas (1) and (2).

$$cos Θ = \frac{{γ}_{SL} - {γ}_{SLO} + \frac{C}{2} {V}^{2}}{{γ}_{L}} \qquad [ Math . 3 ]$$

As is apparent from Formula (3), when a voltage is applied, the value of cos θ is larger than when no voltage is applied, and thus the value of θ also becomes larger. That is, when a voltage is applied, an angle between the surface tension γ_{L} of the treatment liquid and the surface of the insulator 26 becomes larger than when no voltage is applied.

Therefore, as shown in FIG. 7, in the treatment liquid that adheres to the surface of the insulator 26 of the receiving portion 24, an angle between the surface tension γ_{L} of the treatment liquid and the surface of the insulator 26 in a portion corresponding to the first terminal portion 25a to which no voltage is applied is larger than that in a portion corresponding to the second terminal portion 25b to which a voltage is applied. As a result, in the surface tension γ_{L} of the treatment liquid, a force component in a direction along the surface of the insulator 26 becomes smaller. Thus, in the treatment liquid that adheres to the surface of the insulator 26 of the receiving portion 24, a force acts on the portion corresponding to the second terminal portion 25b to which a voltage is applied in the direction along the surface tension γ_{S} of the insulator 26, and the treatment liquid moves in the same direction.

FIG. 8 is a diagram showing an operation of the substrate processing portion 20 according to the present embodiment, particularly when moving a treatment liquid scattered from the substrate S to the receiving portion 24 according to a wettability gradient of the insulator 26 with respect to the treatment liquid.

As shown in FIG. 8, in the treatment liquid that adheres to the surface of the insulator 26 of the receiving portion 24, an angle between the surface tension γ_{L} of the treatment liquid and the surface of the insulator 26 in a portion corresponding to a second insulator 26B having high wettability with respect to the treatment liquid is larger than that in a portion corresponding to a first insulator 26A having low wettability with respect to the treatment liquid. As a result, in the surface tension γL of the treatment liquid, a force component in a direction along the surface of the insulator 26 becomes smaller. Thus, in the treatment liquid that adheres to the surface of the insulator 26 of the receiving portion 24, a force acts on the portion corresponding to the second insulator 26B having high wettability with respect to the treatment liquid in a direction along the surface tension γS of the insulator 26, and the treatment liquid moves in the same direction. That is, the application of a voltage to the electrode 25 and a wettability gradient of the insulator 26 with respect to the treatment liquid act synergistically on the receiving portion 24, and thus the movement of the treatment liquid adhered to the surface of the insulator 26 of the receiving portion 24 is promoted.

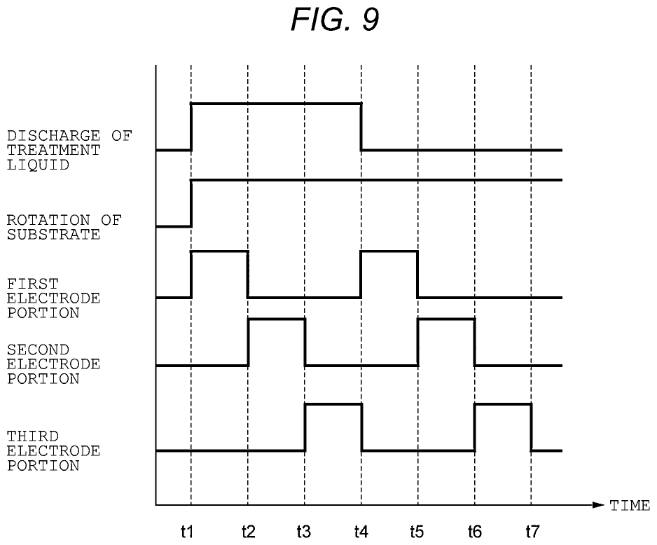

Next, a flow of a substrate processing method executed by the substrate processing apparatus 10 according to the present embodiment will be described with reference to a timing chart of a sequence diagram shown in FIG. 9. The substrate processing method in the embodiment can be performed, for example, as a portion of the manufacture of the semiconductor device MDV.

As shown in FIG. 9, when the processing of the substrate processing apparatus 10 is started, first, a treatment liquid is discharged onto the substrate S from the supply portion 22 at time t1. At time t1, the substrate S held by the holding portion 21 is rotated by the rotation driving portion 23. At time t1, a voltage is applied to the first electrode 25A by the voltage control portion 27.

Next, at time t2, a voltage is applied to the second electrode 25B by the voltage control portion 27.

Next, at time t3, a voltage is applied to the third electrode 25C by the voltage control portion 27.

That is, voltages are sequentially applied to the first electrode 25A, the second electrode 25B, and the third electrode 25C while the substrate S held by the holding portion 21 is rotated after the treatment liquid is discharged onto the substrate S from the supply portion 22.

Next, at time t4, the discharge of the treatment liquid from the supply portion 22 to the substrate S is stopped. At time t4, a voltage is applied to the first electrode 25A by the voltage control portion 27.

Next, at time t5, a voltage is applied to the second electrode 25B by the voltage control portion 27.

Next, at time t6, a voltage is applied to the third electrode 25C by the voltage control portion 27.

That is, voltages are sequentially applied to the first electrode 25A, the second electrode 25B, and the third electrode 25C while the substrate S held by the holding portion 21 is rotated even after the discharge of the treatment liquid from the supply portion 22 to the substrate S is stopped.

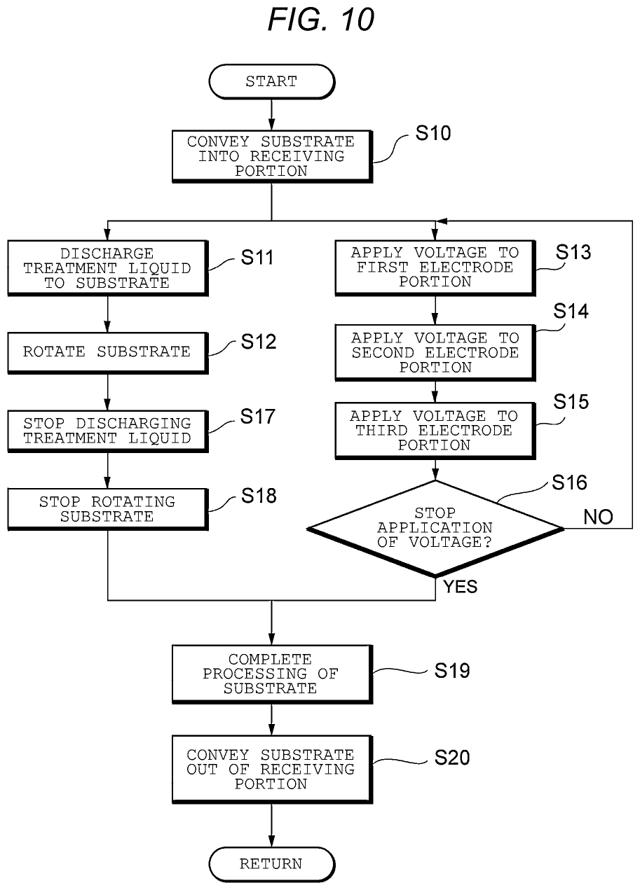

Next, a flow of the substrate processing method executed by the substrate processing apparatus 10 according to the present embodiment will be described with reference to a flowchart shown in FIG. 10.

As shown in FIG. 10, the substrate processing apparatus 10 first conveys a substrate into the receiving portion 24 (step S10).

Next, the substrate processing apparatus 10 discharges a treatment liquid onto the substrate S by the supply portion 22 (step S11).

Next, the substrate processing apparatus 10 rotates the substrate S, that is held by the holding portion 21, by the rotation driving portion 23 (step S12). Step S11 and step S12 may be performed at the same time.

Next, the substrate processing apparatus 10 applies a voltage to the first electrode 25A by the voltage control portion 27 in parallel with the discharge of the treatment liquid onto the substrate S by the supply portion 22 (step S13).

Next, the substrate processing apparatus 10 applies a voltage to the second electrode 25B by the voltage control portion 27 (step S14).

Next, the substrate processing apparatus 10 applies a voltage to the third electrode 25C by the voltage control portion 27 (step S15).

Next, the substrate processing apparatus 10 determines whether to stop applying a voltage by the voltage control portion 27 (step S16). When the substrate processing apparatus 10 determines that the application of a voltage by the voltage control portion 27 is not to be stopped (step S16=NO), the processing returns to step S13, and repeats the processing from step S13 to step S15 until it is determined that the application of a voltage by the voltage control portion 27 is to be stopped.

The substrate processing apparatus 10 stops discharging the treatment liquid onto the substrate S by the supply portion 22 (step S17), and then continues to rotate the substrate S to scatter the treatment liquid from the substrate S and dry the substrate S. Thereafter, the substrate processing apparatus 10 stops rotating the substrate S by the rotation driving portion 23 (step S18). A timing at which the application of a voltage by the voltage control portion 27 is stopped may be, for example, a timing after the discharge of the treatment liquid onto the substrate S is stopped or a timing after the rotation of the substrate S is stopped.

Next, the substrate processing apparatus 10 completes the processing of the substrate S (step S19). Here, the substrate processing apparatus 10 may omit processing for determining whether the processing of the substrate S is completed by setting various conditions regarding the processing of the substrate S in advance.

Thereafter, the substrate processing apparatus 10 conveys the substrate S out of the receiving portion 24 (step S20), and ends the flowchart shown in FIG. 10.

Next, an operation of the substrate processing apparatus 10 according to the present embodiment will be described.

In the substrate processing apparatus 10, when the treatment liquid is supplied to the substrate S from the supply portion 22 and the substrate S held by the holding portion 21 is rotated by the rotation driving portion 23, a portion of the treatment liquid scattered from the substrate S is received in the receiving portion 24. When the treatment liquid received in the receiving portion 24 remains, there is a concern that the remaining treatment liquid may adhere to the substrate S again with the elapse of time and may affect the processing of the substrate S.

Therefore, in the present embodiment, the voltage control portion 27 applies voltages to the first electrode 25A, the second electrode 25B, and the third electrode 25C, that are disposed in order from the upper side to the lower side in the direction of gravity, and thus the treatment liquid received in the receiving portion 24 is urged to move downward along the inner surface of the receiving portion 24 according to gravity.

In the present embodiment, the wettability of the insulator 26 with respect to the treatment liquid has further gradient from the upper side to the lower side in the direction of gravity, and thus the treatment liquid received in the receiving portion 24 is more urged to move downward along the inner surface of the receiving portion 24 according to gravity.

That is, due to the synergistic effect of the application of a voltage to the electrode 25 and a wettability gradient of the insulator 26 with respect to the treatment liquid, the treatment liquid received in the receiving portion 24 is even more urged to move downward along the inner surface of the receiving portion 24 according to gravity.

Thus, retention of the treatment liquid in the receiving portion 24 is prevented, and influence on the processing of the substrate S due to re-adhesion of the treatment liquid to the substrate S is prevented.

The above-described embodiment can also be implemented in the following configurations. The configurations may be implemented independently or may be combined with each other.

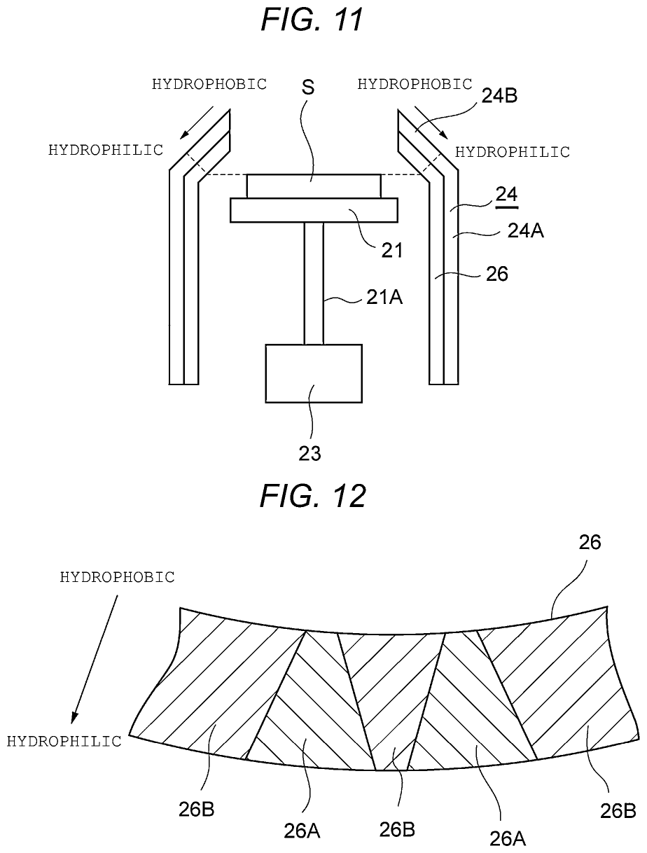

In the embodiment described above, as shown in FIG. 11, in the extending portion 24B of the receiving portion 24, the insulator 26 may have a wettability gradient with respect to the treatment liquid along the direction of gravity so that wettability with respect to the treatment liquid gradually increases from the upper side to the lower side in the direction of gravity. The wettability gradient with respect to the treatment liquid is provided at least at a surface portion located above the upper surface of the substrate S held by the holding portion 21 in the direction of gravity on a receiving surface (inner wall surface) of the extending portion 24B of the receiving portion 24, in which the receiving surface receives the treatment liquid scattered from the substrate S held by the holding portion 21. Here, the receiving surface is a surface provided at a position to which the treatment liquid scattered from the substrate S held by the holding portion 21 adheres. For example, the receiving surface is a surface provided outside the substrate S and above the upper surface of the substrate S held by the holding portion 21 in the direction of gravity.

In the embodiment described above, as shown in FIG. 12, the insulator 26 may include the first insulator 26A and the second insulator 26B that has lower wettability with respect to the treatment liquid than that of the first insulator 26A. The first insulator 26A may be made of, for example, a hydrophilic material, and the second insulator 26B may be made of, for example, a hydrophobic material. In the example shown in the drawing, the first insulator 26A and the second insulator 26B are disposed alternately in the circumferential direction centering on the center of the opening of the receiving portion 24. The first insulator 26A has a tapered shape in which the width thereof in the circumferential direction centering on the center of the opening of the receiving portion 24 gradually increases outward from the inside in the radial direction centering on the center of the opening of the receiving portion 24. In other words, the width of the first insulator 26A gradually increases from the upper side to the lower side of the receiving portion 24. The second insulator 26B has an inverted tapered shape in which the width thereof in the circumferential direction centering on the center of the opening of the receiving portion 24 gradually decreases outward from the inside in the radial direction centering on the center of the opening of the receiving portion 24. In other words, the width of the second insulator 26B gradually decreases from the upper side to the lower side of the receiving portion 24. Thereby, from the inside to the outside in the radial direction centering on the center of the opening of the receiving portion 24, the ratio of hydrophobic areas decreases, while the ratio of hydrophilic areas increases, and a wettability gradient with respect to the treatment liquid is formed such that wettability with respect to the treatment liquid increases gradually.

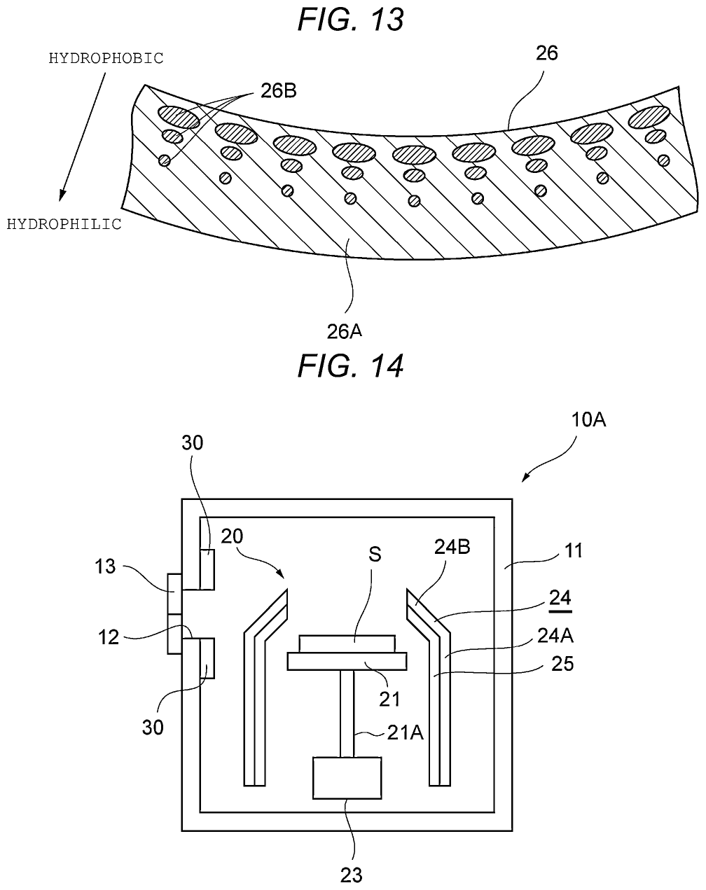

In the embodiment described above, as shown in FIG. 13, the insulator 26 may include the first insulator 26A and the second insulator 26B that has higher wettability with respect to the treatment liquid than that of the first insulator 26A. The first insulator 26A may be made of, for example, e a hydrophilic material, and the second insulator 26B may be made of, for example, a hydrophobic material. In the example shown in the drawing, in the insulator 26, a plurality of circular second insulators 26B are radially arranged in parallel in the radial direction centering on the center of the opening of the receiving portion 24, and the other areas are configured as the first insulator 26A. The second insulator 26B is formed such that the size of the second insulator 26B gradually decreases from the inside to the outside in the radial direction centering on the center of the opening of the receiving portion 24. In other words, the size of the second insulator 26B gradually decreases from the upper side to the lower side of the receiving portion 24. Thereby, from the inside to the outside in the radial direction centering on the center of the opening of the receiving portion 24, the ratio of hydrophobic areas decreases, while the ratio of hydrophilic areas increases, and a wettability gradient with respect to the treatment liquid is formed such that wettability with respect to the treatment liquid increases gradually.

In the embodiment described above, as shown in FIG. 14, the substrate processing apparatus 10A may be provided with an electrode 30 on a surface portion corresponding to the carry-in port 12 on the inner surface of the housing 11. For example, the electrode 30 may be provided above and/or below the carry-in port 12. Thereby, when the substrate S held by the holding portion 21 is rotated and the treatment liquid is scattered from the substrate S, even if a portion of the scattered treatment liquid is adhered to the surface portion as a receiving portion corresponding to the carry-in port 12 on the inner surface of the housing 11, such treatment liquid is urged to move downward according to gravity. As a result, the treatment liquid is prevented from remaining at the surface portion corresponding to the carry-in port 12 on the inner surface of the housing 11, and the substrate S is prevented from being contaminated with the treatment liquid when the substrate S is carried into the carry-in port 12.

In the embodiment described above, the application of a voltage to the electrode 25 and the wettability gradient of the insulating portion with respect to the treatment liquid act synergistically, thereby promoting the movement of the treatment liquid that adheres to the surface of the insulator 26 of the receiving portion 24. Alternatively, the movement of a treatment liquid that adheres to the surface of the insulator 26 of the receiving portion 24 may be promoted only by applying a voltage to the electrode 25 without the insulator 26 having the wettability gradient with respect to the treatment liquid.

### APPENDIX

The technical ideas that can be understood from the above-described embodiment are described below.

### Appendix 1

A substrate processing apparatus including:
a holder that holds a substrate;
a supply nozzle that supplies a treatment liquid to the substrate held by the holder;
a rotation driver that rotates the substrate held by the holder;
a receiving portion that receives the treatment liquid scattered from the substrate held by the holder;
an electrode that is provided on a surface of the receiving portion that receives the treatment liquid;
an insulator that covers an electrode surface of the electrode; and
a voltage controller that controls a voltage to be applied to the electrode.

### Appendix 2

The substrate processing apparatus according to appendix 1, wherein
the electrode includes
   a first electrode, and
   a second electrode that is provided adjacent to the first electrode on a lower side of the first electrode in a direction of gravity, and
the voltage controller applies voltages to the first electrode and the second electrode at different timings.

### Appendix 3

The substrate processing apparatus according to appendix 1 or 2, wherein
the insulator includes
   a first insulator, and
   a second insulator that has lower wettability with respect to the treatment liquid than that of the first insulator.

### Appendix 4

The substrate processing apparatus according to appendix 3, wherein
the first insulator is made of a hydrophilic material, and
the second insulator is made of a hydrophobic material.

### Appendix 5

The substrate processing apparatus according to appendix 3 or 4, wherein the insulator has a wettability gradient with respect to the treatment liquid in a direction along the direction of gravity so that the wettability with respect to the treatment liquid gradually increases from an upper side to a lower side in the direction of gravity.

### Appendix 6

The substrate processing apparatus according to appendix 5, wherein the wettability gradient with respect to the treatment liquid is provided at least at a surface of a receiving surface of the treatment liquid in the receiving portion, the surface of the receiving surface being located above an upper surface of the substrate held by the holder in the direction of gravity.

### Appendix 7

The substrate processing apparatus according to any one of appendices 3 to 6, wherein the first insulator and the second insulator are disposed such that at least portions of the respective insulators overlap in a direction along a receiving surface of the treatment liquid in the receiving portion and in a direction along the direction of gravity.

### Appendix 8

The substrate processing apparatus according to any one of appendices 1 to 7, wherein the electrode is provided at least on a surface of a receiving surface of the treatment liquid in the receiving portion, the surface of the receiving surface being located above an upper surface of the substrate held by the holder in a direction of gravity.

### Appendix 9

The substrate processing apparatus according to any one of appendices 1 to 8, wherein the voltage controller applies a voltage to the electrode on a condition that the substrate is held by the holder.

### Appendix 10

A substrate processing method including:
holding a substrate;
supplying a treatment liquid to the held substrate;
rotating the held substrate;
receiving the treatment liquid scattered from the held substrate; and
controlling a voltage to be applied to an electrode while an electrode surface of the electrode provided on a surface portion receiving the treatment liquid is covered with an insulator.

### Appendix 11

A semiconductor device manufacturing method including:
forming a resist pattern on a substrate, that is a semiconductor substrate, processed by the substrate processing apparatus according to any one of appendices 1 to 9; and
processing the substrate based on the resist pattern to form a semiconductor element.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a holder configured to hold a substrate;
a supply nozzle configured to provide a treatment liquid to the substrate;
a rotation driver configured to rotate the substrate;
a receiving portion configured to receive the treatment liquid scattered from the substrate;
an electrode provided on a surface of the receiving portion and configured to receive the treatment liquid;
an insulator covering an electrode surface of the electrode; and
a voltage controller configured to control a voltage to be applied to the electrode.

2. The substrate processing apparatus according to claim 1, wherein
the electrode includes:
a first electrode; and
a second electrode disposed adjacent to the first electrode on a lower side of the first electrode in a direction of gravity, and
wherein the voltage controller is configured to apply voltages to the first electrode and the second electrode at respective timings.

3. The substrate processing apparatus according to claim 1, wherein
the insulator includes:
a first insulator with a first wettability with respect to the treatment liquid; and
a second insulator with a second wettability with respect to the treatment liquid, the second wettability being lower than the first wettability.

4. The substrate processing apparatus according to claim 3, wherein
the first insulator includes a hydrophilic material, and
the second insulator includes a hydrophobic material.

5. The substrate processing apparatus according to claim 3, wherein the insulator has a wettability gradient with respect to the treatment liquid in a direction along the direction of gravity, so that the wettability with respect to the treatment liquid gradually increases from an upper side to a lower side in the direction of gravity.

6. The substrate processing apparatus according to claim 5, wherein the wettability gradient with respect to the treatment liquid is provided at least at a surface of a receiving surface of the treatment liquid in the receiving portion, the surface of the receiving surface being located above an upper surface of the substrate held by the holder in the direction of gravity.

7. The substrate processing apparatus according to claim 3, wherein the first insulator and the second insulator are disposed, such that at least portions of the respective insulators overlap in a direction along a receiving surface of the treatment liquid in the receiving portion and in a direction along the direction of gravity.

8. The substrate processing apparatus according to claim 1, wherein the electrode is provided at least on a surface of a receiving surface of the treatment liquid in the receiving portion, the surface of the receiving surface being located above an upper surface of the substrate held by the holder in a direction of gravity.

9. The substrate processing apparatus according to claim 1, wherein the voltage controller is configured to apply a voltage to the electrode when the substrate is held by the holder.

10. A substrate processing method comprising:
holding a substrate;
supplying a treatment liquid to the held substrate;
rotating the held substrate;
receiving the treatment liquid scattered from the held substrate; and
controlling a voltage applied to an electrode when an electrode surface of the electrode provided on a surface portion receiving the treatment liquid is covered with an insulator.

11. The substrate processing apparatus according to claim 1, further comprising:
forming a resist pattern on the substrate; and
processing the substrate based on the resist pattern to form a semiconductor element.

12. The substrate processing method according to claim 10, wherein
the electrode includes:
a first electrode; and
a second electrode disposed adjacent to the first electrode on a lower side of the first electrode in a direction of gravity, and
wherein voltages applied to the first electrode and the second electrode are at different timings.

13. The substrate processing method according to claim 10, wherein
the insulator includes:
a first insulator with a first wettability with respect to the treatment liquid; and
a second insulator with a second wettability with respect to the treatment liquid, the second wettability being lower than the first wettability.
